(19) United States
(12) Patent Application Publication
(10) Pub. No.: US 2003/0052084 A1
(43) Pub. Date: Mar. 20, 2003

(54) In-situ or ex-situ profile monitoring of phase openings on alternating phase shifting masks by scatterometry

(76) Inventors: Cyrus E. Tabery, Cupertino, CA (US); Khoi A. Phan, San Jose, CA (US); Bharath Rangarajan, Santa Clara, CA (US); Bhanwar Singh, Morgan Hill, CA (US); Ramkumar Subramanian, Sunnyvale, CA (US)

Correspondence Address: Himanshu S. Amin, Amin & Turocy, LLP, National City Center, 1900 E. 9th Street, 24th floor, Cleveland, OH, 44114, US

(21) Appl. No.: 09/955,517

(22) Filed: Sep. 18, 2001

(51) Int. Cl. G01L 21/30; G01R 31/00

(52) U.S. Cl. 216/59

(57) ABSTRACT

A system for monitoring and controlling aperture etching in an alternating aperture phase shift mask is provided. The system includes one or more light sources, each light source directing light to one or more apertures etched on a mask. Light reflected from the apertures is collected by a measuring system, which processes the collected light. The collected light is indicative of properties including the depth, width and/or profile of the openings on the mask. The measuring system provides such depth, width and/or profile related data to a processor that determines the acceptability of the aperture and/or the mask. The system also includes a plurality of etching devices associated with etching apertures in the mask. The processor may selectively control the etching devices so as to regulate aperture etching.

### TECHNICAL FIELD

The present invention generally relates to semiconductor processing, and in particular to a system and method for measuring, monitoring and/or controlling the fabrication of phase openings in an alternating aperture phase shift mask.

### BACKGROUND

A photomask (a.k.a. mask) can be employed in semiconductor manufacturing to transfer a pattern onto a wafer. The pattern to be transferred onto the wafer can be formed on a substantially transparent blank structure by standard photolithography processes, for example. Typically, the substantially transparent blank structure is a substrate like quartz, which may include thin films of metal or other nontransparent material (e.g., chrome material) to block light passing through the substrate.

The process of manufacturing phase shifting masks may consist of hundreds of steps. One such step is depositing a chrome layer on a clean substrate layer. Once deposited, openings (apertures) are etched into the chrome layer. Similarly, mask fabrication also involves one or more quartz etching steps. During the quartz etching, the patterned binary masks (e.g., chromium on quartz) can be fabricated to achieve the phase difference between alternating sides of the chromium-covered quartz. Controlling parameters like the width, depth and trench wall angles of the openings etched into the chrome layer and controlling the depth, width and trench wall angles of trenches carved into the substrate (e.g., quartz, SiO₂) is required to enable controlled phase shifting of light that will pass through the mask. Conventional mask fabrication methods may not provide fine enough control of the aperture fabrication (e.g., etching) process and thus desired phase shifting may not be achieved.

The process of manufacturing semiconductors, (integrated circuits, ICs, chips), employing phase shift masks typically consists of more than a hundred steps, during which hundreds of copies of an integrated circuit may be formed on a single wafer. Generally, the process involves creating several patterned layers on and into the substrate that ultimately forms the complete integrated circuit. The patterned layers are created, in part, by the light that passes through phase shift masks. Thus, processing the positive or negative of the pattern into the mask is important in fabricating the chips.

The requirement of small features with close spacing between adjacent features requires sophisticated manufacturing techniques, including high-resolution photolithographic processes employing phase shift masking. Fabricating a semiconductor using such sophisticated techniques may involve a series of steps including exposing the photo resist one or more times to one or more light sources (where the phase of the light may be shifted). In conventional lithography, an exposure is performed using a single mask where the photo resist is exposed by a single radiation source. The resolution, which is typically defined as the smallest distance two features can be spaced apart while removing all photo resist between the features, is equal to:

D=k1*(λ/NA)

where d is the resolution, λ is the wavelength of the exposing radiation, NA is the numerical aperture of the lens, and k1 is a process dependent constant typically having a value of approximately 0.5. While resolution may be improved by decreasing the wavelength or by using a lens with a larger NA, decreasing the wavelength and increasing the numerical aperture decreases the depth of focus (since depth of focus is proportional to λ/NA²), which creates additional problems. Thus, several techniques have been developed to enhance the resolution of conventional lithography to enable formation of patterned resist layers with smaller dimensions than those achievable with conventional methods. For example, phase-shifted masks (PSM) have been developed. In a PSM mask, features are surrounded by light transmitting regions that shift the phase of the transmitted light compared to the feature. Masks may be constructed to shift the phase of the light varying amounts, including, but not limited to, 30 degrees, 60 degrees, 90 degrees, and 180 degrees. In this way, the diffraction fringes at the edges of the features can be effectively cancelled, resulting in a better image contrast and improved quality chips.

The resolution of both conventional and enhanced resolution lithographic processes is better for periodic features, such as those found in memory devices (e.g. DRAMs) because a greater percentage of the exposing radiation is contained in the diffraction nodes of the periodic structures compared to that contained in the diffraction nodes of isolated features. For example, prior art FIG. 15 illustrates an aerial plot of intensity under a mask 1500 having an isolated feature 1502 and periodic features 1510, 1512, and 1514 having a dimension near the resolution limit of the process. The contrast (difference in intensity) between masked and unmasked regions is much greater for the periodic features 1510, 1512 and 1514 (curve 1506) than for the isolated feature 1502 (curve 1508). Thus, for a given combination of exposing conditions, at some dimension, isolated feature 1502 cannot be resolved simultaneously with the periodic features 1510, 1512 and 1514 that are within the resolution limit of the process.

Phase shift masks take advantage of light passing through one or more apertures (apertures) on a mask employed in chip manufacturing being diffracted. Diffraction is a property of wave motion, in which waves spread and bend when passed through small apertures or around barriers. A mask may have many such apertures and barriers. The bending and/or spreading of the light waves is more pronounced when the size of the aperture or the barrier approximates or is smaller than the wavelength of the incoming wave. With feature sizes approaching and becoming smaller than the wavelength of the exposing light, the apertures and/or barriers on the mask have thus become closer to the wavelength of the exposing light. Thus attention to diffraction in chip manufacturing has become more pronounced since diffraction can lead, for example, to rounded features and features that do not have a desired size and/or shape.

For example, in prior art FIG. 16, a light source is directing light waves 1620 at a mask 1622. Some of the light waves 1620 pass through an aperture 1626 that is close to the size of the wavelength of the light waves 1620. The mask 1622 has been designed to develop a region 1638 on a photo resist layer 1624, so that two desired features 1642 and 1644 can be formed. The features 1642 and 1644 are desired to be rectangular, with substantially square edges. The aperture 1626 is small because the desired features 1642 and 1644 are correspondingly small.

With conventional lithography, the light waves 1620 may pass directly through the aperture 1626, exposing the region 1638, but the light waves 1620 may also be diffracted as illustrated by light waves 1628, 1630 and 1632. The diffracted wave 1628 has exposed a region 1634 and the diffracted wave 1630 has exposed a region 1636. Neither region 1634 nor region 1636 were intended to be exposed. Further, diffracted wave 1632 has exposed a triangular area 1640. Thus the desired feature 1644 may not have a substantially square edge due to the undesired region 1640 being exposed by the diffracted wave 1632. Phase shift masking mitigates the diffraction problems described above by accounting for and counter-acting the diffraction effects noted above. Other well known problems associated with psm include the proximity effect, phase contradiction, phase transition and line width problems.

A theory explaining diffraction is that each point of a wave on a flat wave front may be a source of secondary, spherical wavelets. Before reaching a barrier or aperture, the secondary wavelets may add to the original wave front. When the wave front approaches an aperture or barrier, the wavelets approaching the unobstructed region pass through the barrier, while other wavelets do not pass. When the size of the aperture approaches the wavelength of or is smaller than the wavelength of the incoming wave, only a few wavelets may pass through the aperture. The wavelets that pass through the aperture or around the barrier may then be a source of more wavelets that expand in all directions from the point of the obstruction, and the shape of the new wave front is curved. The wavelets of these diffracted, or bent, waves can now travel different paths and subsequently interfere with each other, producing interference patterns. The shape of these patterns depends on the wavelength and the size of the aperture or barrier. Diffraction can be thought of as the interference of a large number of coherent wave sources, and thus, diffraction and interference are substantially similar phenomenon.

### SUMMARY OF THE INVENTION

The following presents a simplified summary of the invention in order to provide a basic understanding of some aspects of the invention. This summary is not an extensive overview of the invention. It is not intended to identify key or critical elements of the invention or to delineate the scope of the invention. Its sole purpose is to present some concepts of the invention in a simplified form as a prelude to the more detailed description presented later.

The present invention provides a system that facilitates monitoring, measuring and/or controlling the fabrication of openings (apertures) in alternating aperture phase shift masks employed in semiconductor manufacturing. Such alternating aperture phase shift masks can include, but are not limited to, sidewall chrome alternating aperture (SCAA) masks, asymmetric lateral biased alternating aperture masks, additive alternating aperture masks, undercut alternating aperture masks, dual trench (with and without undercut) alternating aperture masks, mask-phase-only alternating aperture masks, chromeless alternating phase shift masks, and uncompensated alternating phase-shift masks. Controlling the mask fabrication process with runtime feedback provides superior mask fabrication as compared to conventional systems and thus facilitates achieving smaller feature sizes with improved shapes via more precise control of phase shifting of light passing through the phase shift mask. Measuring apertures after fabrication is substantially complete facilitates improving quality control and thus facilitates achieving smaller feature sizes with improved shapes via more precise control of phase shifting.

An exemplary system may employ one or more light sources arranged to project light onto one or more apertures and/or gratings on a mask being fabricated and one or more light sensing devices (e.g., photo detector, photodiode) for detecting light reflected and/or refracted by the one or more apertures and/or gratings. The light reflected from the one or more apertures is indicative of at least one parameter of the mask fabrication process (e.g., depth of opening, width of opening, trench wall slope). The depth, width and/or trench wall angles of the apertures are important to the fidelity of the image transfer process due to effects on phase shifting and diffraction, and thus monitoring the depth, width and/or trench wall angles of the apertures in the masks enables fabricating higher quality complimentary phase shift masks as compared to conventional systems.

A diffraction grating is an optical device that is used to determine the different wavelengths or colors contained in a beam of light. The apertures in a phase shift mask may operate, at least in part, similarly to a diffraction grating in that light will be reflected and dispersed when directed onto an aperture. A diffraction grating may include a reflecting surface, on which numerous narrow parallel grooves have been etched close together. A mask may contain numerous apertures, and/or gratings, etched closely together, which similarly will reflect and diffract light. A beam of light directed at such a surface is scattered, or diffracted, in all directions at each such aperture and/or grating. Such scattering will be affected by the depth, width and/or trench wall angles of the apertures etched in the mask. The light waves reinforce each other in certain directions and cancel out in other directions, creating unique signatures for different wavelengths and/or angles of incidence of the light directed onto the mask.

Limitations due to the wavelength of light used to transfer a pattern cause resolution at the edges of the patterns of the mask to degrade. A phase-shifting mask (psm) can be employed to increase the resolution of a pattern on a wafer by creating phase-shifting regions in the transparent areas of the mask. A standard psm may be fabricated by depositing transparent films of appropriate thickness on a mask and then patterning the films over the desired transparent areas using a second level lithography and etch technique. Alternatively, and/or additionally, fabricating a psm may involve etching vertical trenches in the substrate. Both techniques produce “edges” or “walls” between the phase-shifted and unshifted regions that result in a transition between high and low refractive index regions. Fabricating an alternating aperture psm using such techniques has been complicated because conventional techniques may not include etch stop or end point control during the manufacturing of the phase-shift pattern or during the repair of the phase-shift pattern.

Such “alternating aperture” or “Levenson-type” psm include transmission regions (light transmitted through the substantially transparent regions) on either side of a patterned opaque feature. A first transmission region can be phase-shifted from a second transmission region, with both regions transmitting approximately 100% of the incident radiation. Such phase-shift regions can be of different degrees (e.g., 0°, 60°, 120°, or 180°). Light diffracted below such opaque regions from the phase-shifted regions cancels and thus creates a null, or “dark area.” The precision with which the dark area can be created depends, at least in part, on the precision with which the substantially transparent regions (e.g., apertures) can be formed. Such apertures have dimensions including depth, width, and slope angle of trench walls that have historically been measured using techniques that suffer from drawbacks and/or limitations.

A psm depends on interference of ordered light. Light can be modeled as waves propagating through space, where the waves have a wavelength and an intensity. Wavelength is related to the color of the light and intensity is related to the brightness of the light. Incoherent light, (e g., the light to which we are normally exposed), includes waves of various lengths and intensities, traveling in different directions. Coherent light (e.g., laser light) can be produced so that the waves share a common wavelength, a common intensity and have their peaks in phase. Interference, both constructive and destructive, can be employed with coherent light in a psm. However, the constructive and destructive effects depend, at least in part, on the precision with which apertures and/or opaque regions on a mask can be fabricated. Apertures that are too shallow, too deep, too narrow, too wide and/or that have trench walls of an undesired slope will not produce the desired interference, and thus reduce the quality of the pattern transferred to a wafer.

In the semiconductor industry, there is a continuing trend toward higher device densities. To achieve these high densities there have been, and continue to be, efforts toward scaling down device dimensions (e.g., at sub-micron levels) on semiconductor wafers. In order to accomplish such high device packing densities, smaller features sizes and more precise feature shapes are required. This may include the width and spacing of interconnecting lines, spacing and diameter of contact holes, and the surface geometry, such as corners and edges, of various features. When feature sizes become so small that they approach and or become smaller than the wavelength of the exposure light used in semiconductor manufacturing, complex exposure techniques including the use of an alternating aperture phase shift mask (aapsm) may be employed. The ability to control the phase shift of the light passing through a mask is important to achieving the desired critical dimensions on the chip. An aapsm may be used, for example, to fabricate mask patterns that are highly repetitive (e.g., DRAM, memory). An aapsm employed in such processes may have a shifter fabricated in alternating apertures in the mask, where the shifter is fabricated, for example, by recoating a standard binary mask with a photoresist and writing the mask one or more subsequent times. The wavelengths that can be employed with such an aapsm depend, at least in part, on the depth to which the aperture is etched. Shifter etch depth in an aapsm can be modeled by:

Δφ=2πd(n−1)/λ,

for example, where Δφ is the phase shift, d is the depth difference between the shifted and unshifted spaces, n is the index of refraction, and λ is the wavelength. Thus, the phase shift depends, at least in part, on the depth difference between shifted and unshifted spaces and thus an improved method for monitoring, measuring and/or controlling the depth differences is desired to improve chip quality.

In accordance with an aspect of the present invention, a system for measuring, monitoring and/or controlling aperture fabrication (e.g., etching) in an alternating aperture phase shift mask is provided. The system includes etching components operative to etch apertures in the mask and an etching component driving system for driving the one or more etching components. The system also includes components for directing light on to the apertures being etched in the mask and a measuring system for measuring aperture parameters based on light reflected from the apertures. The measuring system includes a scatterometry system for processing the light reflected from the one or more apertures and/or one or more gratings and a processor operatively coupled to the measuring system and the etching component driving system. The processor receives aperture data from the measuring system and uses the data to at characterize the apertures. In one example of the present invention, the processor can also be employed to at least partially control the etching components to regulate the etching of the one or more apertures. One or more etching components may be employed in fabricating a particular mask. It is to be appreciated that any suitable etching components may be employed with the present invention. The etching components are selectively driven by the system to etch the openings in the mask to a desired depth, shape and/or width. The etching process is monitored by the system by comparing signatures generated by the light reflected by the mask to desired signatures. By comparing desired signatures to measured signatures, runtime feedback may be employed to more precisely control the aperture etching and as a result more optimal aperture etching is achieved, which in turn increases fidelity of image transfer, because more precise phase shifting and the resulting interference and cancellation is possible.

Another aspect of the present invention provides a method for measuring, monitoring and/or controlling aperture etching in an alternating aperture phase shift mask. The method includes fabricating (e.g., etching) features (e.g., apertures, gratings) on the mask and while such features are being fabricated and/or after such features have been fabricated, directing light onto at least one of the features and collecting light reflected from and/or refracted by the features. The reflected and/or refracted light is analyzed to determine parameters like the depth, width and/or profile of the features via scatterometry. In response to the analysis of the reflected and/or refracted light, ex-situ analyses may be employed to determine whether to keep a mask or to scrap a mask. In one example of the present invention, the analysis of the reflected and/or refracted light can be employed, in-situ, to control, at least in part, the fabrication performed by the fabrication components to improve the fabrication of the features in the mask.

Still another aspect of the present invention provides a method for measuring, monitoring and/or controlling aperture etching in an alternating aperture phase shift mask. The method includes using etching components to etch apertures and/or gratings in the mask, determining the acceptability of the apertures and/or gratings etched in mask and using in-situ coordinating control of the etching components to more optimally etch the apertures in the mask and/or ex-situ monitoring to determine whether an acceptable mask has been fabricated.

Yet another aspect of the present invention provides a system for monitoring and controlling a process for etching openings in an alternating aperture phase shift mask. The system includes means for sensing the depth, width and/or profile of apertures and/or gratings on the mask, means for etching apertures on the mask and means for selectively controlling the means for etching.

To the accomplishment of the foregoing and related ends, the invention, then, comprises the features hereinafter fully described and particularly pointed out in the claims. The following description and the drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

The present invention is illustrated by way of example in the accompanying figures.

FIG. 1 illustrates a scatterometry beam being directed at a phase shift mask, in accordance with an aspect of the present invention.

FIG. 2 illustrates a scatterometry beam being directed at a phase shift mask where a photoresist pattern is still in place, in accordance with an aspect of the present invention.

FIG. 3 illustrates a scatterometry beam being directed at the bottom of a phase shift mask, in accordance with an aspect of the present invention.

FIG. 4 is a simplified block diagram of a monitoring and controlling system, in accordance with an aspect of the present invention.

FIG. 5 illustrates a phase shift mask at different stages of development as processed in accordance with an aspect of the present invention.

FIG. 6 illustrates a light beam being reflected and/or diffracted from the surface of two phase shift masks; one that is patterned and one that is not, in accordance with an aspect of the present invention.

FIG. 7 is a schematic block diagram of a monitoring and controlling system in accordance with an aspect of the present invention.

FIG. 8 is a partial schematic block diagram of the system of FIG. 7 illustrating one example of a system for measuring phase shift mask opening fabrication in accordance with the an aspect of present invention.

FIG. 9 is a perspective illustration of a mask that may be fabricated in accordance with an aspect of the present invention.

FIG. 10 is a representative three-dimensional grid map of a mask illustrating opening signature measurements taken at grid blocks of the mask in accordance with an aspect of the present invention.

FIG. 11 is a mask opening signature measurement table correlating the mask opening measurements of FIG. 10 with desired values for the mask opening measurements in accordance with the present invention.

FIG. 12 illustrates an exemplary scatterometry system collecting reflected light in accordance with an aspect of the present invention.

FIG. 13 is a flow diagram illustrating an example of a methodology for monitoring, measuring and/or controlling fabrication of openings in a phase shift mask in accordance with an aspect of the present invention.

FIG. 14 is a flow diagram illustrating another example of a methodology for improving mask quality control in accordance with an aspect of the present invention.

Prior Art FIG. 15 is an aerial intensity plot of isolated and periodic structures on a mask.

Prior Art FIG. 16 illustrates conventional lithography where light waves passing through a mask are being diffracted.

FIG. 17 is a simplified perspective view of an incident light reflecting off a surface, in accordance with an aspect of the present invention.

FIG. 18 is a simplified perspective view of an incident light reflecting off a surface, in accordance with an aspect of the present invention.

FIG. 19 illustrates a complex reflected and refracted light produced when an incident light is directed onto a surface, in accordance with an aspect of the present invention.

FIG. 20 illustrates a complex reflected and refracted light produced when an incident light is directed onto a surface, in accordance with an aspect of the present invention.

FIG. 21 illustrates a complex reflected and refracted light produced when an incident light is directed onto a surface, in accordance with an aspect of the present invention.

FIG. 22 illustrates phase and intensity signals recorded from a complex reflected and refracted light produced when an incident light is directed onto a surface, in accordance with an aspect of the present invention.

### DETAILED DESCRIPTION

The present invention will now be described with reference to the drawings, where like reference numerals are used to refer to like elements throughout. The following detailed description is of the best modes presently contemplated by the inventors for practicing the invention. It should be understood that the description of these aspects are merely illustrative and that they should not be taken in a limiting sense.

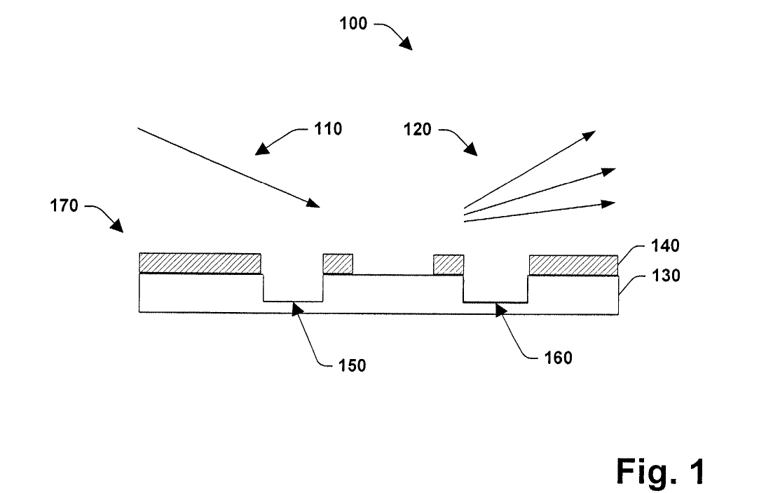

FIG. 1 illustrates a system 100 for measuring, monitoring and/or controlling alternating aperture phase shift mask fabrication. The system 100 includes a scatterometry beam 110 being directed at an alternating aperture phase shift mask 170. The mask 170 is illustrated as including a substantially transparent layer 130 (e.g., quartz) and a substantially opaque layer 140 (e.g., chrome). While the mask 170 is illustrated as including two layers, it is to be appreciated that an alternating aperture phase shift mask with a different number of layers may be fabricated in accordance with the present invention. Furthermore, while the substantially transparent layer may be quartz, it is to be appreciated that other substantially transparent layers may be employed in accordance with the present invention. Further still, while the substantially opaque layer may be chrome, it is to be appreciated that other substantially opaque layers may be employed in accordance with the present invention.

The mask 170 is illustrated with two apertures (e.g., aperture 150, aperture 160). The system 100 can measure parameters of the apertures including, but not limited to, the depth of the apertures, the width of the apertures and the slope angles of the walls of the apertures. Thus, the system 100 can be employed to improve alternating aperture phase shift mask quality, and thus the quality of patterns projected during semiconductor fabrication processes. The system 100 can be employed in-situ (e.g., during fabrication) to control the fabrication of the mask 170 and/or can be employed ex-situ, (e.g., post fabrication) in processes like quality control.

The system 100 operates, at least in part, by directing the beam 110 at the mask 170 and then collecting and analyzing a light 120 reflected and/or refracted by the mask 170. Such analysis is accomplished through scatterometry, which will be discussed below.

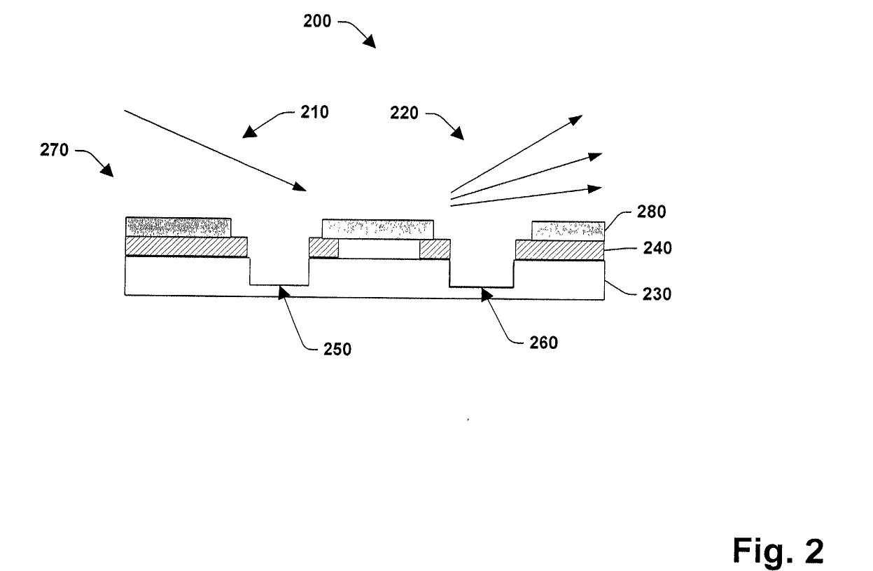

FIG. 2 illustrates a system 200 for measuring, monitoring and/or controlling alternating aperture phase shift mask fabrication. The system 200 includes a scatterometry beam 210 being directed at an alternating aperture phase shift mask 270. The mask 270 is illustrated as including a substantially transparent layer 230 (e.g., quartz), a substantially opaque layer 240 (e.g., chrome) and a photoresist layer 280 that can be employed, for example, in patterning the substantially opaque layer 240.

The mask 270 is illustrated with two apertures (e.g., aperture 250, aperture 260). The system 200 can measure parameters of the apertures including, but not limited to, the depth of the apertures, the width of the apertures and the slope angles of the walls of the apertures. Thus, the system 200 can be employed to improve alternating aperture phase shift mask quality, and thus the quality of patterns projected during semiconductor fabrication processes by, for example, facilitating controlling processing associated with the photoresist layer 280. The system 200 can be employed in-situ (e.g., during fabrication) to control the fabrication of the mask 270 and/or can be employed ex-situ, (e.g., post fabrication) in processes like quality control.

The system 200 operates, at least in part, by directing the beam 210 at the mask 270 and then collecting and analyzing a light 220 reflected and/or refracted by the mask 270. Such analysis is accomplished through scatterometry analysis of signatures generated by the reflected and/or refracted light.

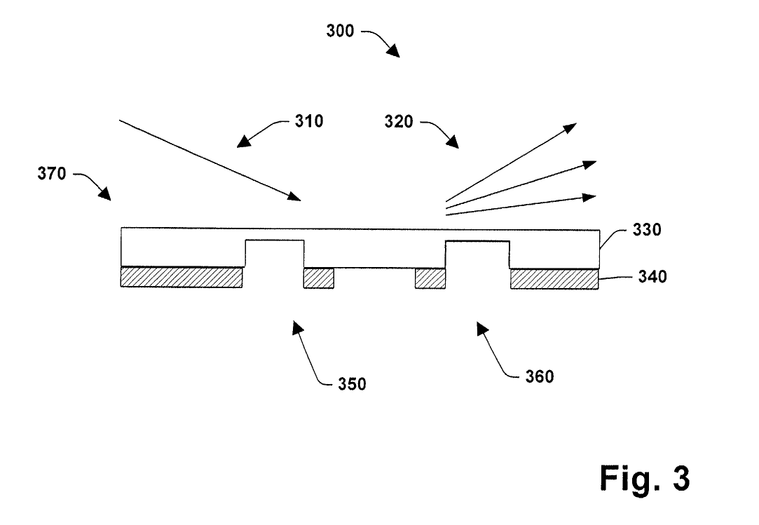

FIG. 3 illustrates a system 300 for measuring, monitoring and/or controlling alternating aperture phase shift mask fabrication. The system 300 includes a scatterometry beam 310 being directed at the bottom of an alternating aperture phase shift mask 370. The mask 370 is illustrated as including a substantially transparent layer 330 (e.g., quartz) and a substantially opaque layer 340 (e.g., chrome). The mask 370 is illustrated with two apertures (e.g., aperture 350, aperture 360). Although the beam 310 is being directed at the bottom of the alternating aperture phase shift mask 370, the system 300 can measure parameters of the mask including, but not limited to, the depth of the apertures, the width of the apertures, the slope angles of the walls of the apertures and the planarity of the bottom surface of the mask 370. Thus, the system 300 can be employed to improve alternating aperture phase shift mask quality, and thus the quality of patterns projected during semiconductor fabrication processes. The system 300 can be employed in-situ (e.g., during fabrication) to control the fabrication of the mask 370 and/or can be employed ex-situ, (e.g., post fabrication) in processes like quality control.

The system 300 operates, at least in part, by directing the beam 310 at the mask 370 and then collecting and analyzing a light 320 reflected and/or refracted by the mask 370. While FIG. 3 illustrates the light 310 being directed only at the bottom of the mask 370, it is to be appreciated that light may be directed at either side and/or both sides of the mask 370 in accordance with the present invention.

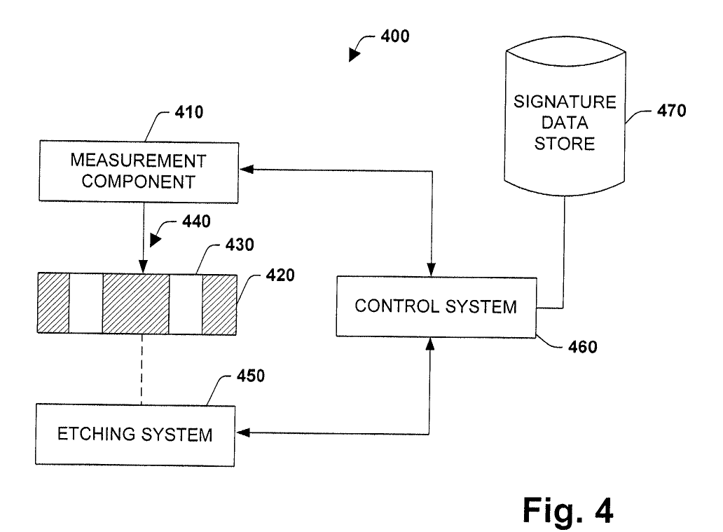

Referring now to FIG. 4, a block diagram of a system 400 for monitoring and/or controlling the shape, depth and/or width of apertures 430 being etched in a mask 420 is illustrated. The mask 420 can be operated on by a mask etching system 450. By way of illustration, the mask etching system 450 is able to etch apertures 430 of various shapes, depths, profiles and widths in the mask 420.

The system 400 also includes a measurement component 410 operable to measure the shape, depth, profile and/or width of the apertures 430 in the mask 420. The measurement component 410 includes, for example, a light source that emits a beam 440 incident to the surface of the mask 420. The beam 440 interacts with the mask 420 and the apertures 430 in the mask 420 and thus is reflected and/or diffracted. The measurement component 410 also includes a detection system for detecting the reflected and/or diffracted light (also indicated as 440 for purposes of brevity). Characteristics (e.g. shape, depth, width) of the apertures 430 are determined based on the properties of the reflected and/or diffracted light 440. The system 400 also includes a control system 460 operatively coupled to the etching system 450 and the measurement component 410. The control system 460 is programmed and/or configured to control operation of the etching system 450. Other mask fabrication parameters including, but not limited to horizontal development rate, vertical development rate and development-rate percent uniformity may also be monitored.

It is to be appreciated that the surface of the mask 420, which may include features on and/or in the mask 420 being processed, can both reflect and refract the light 440, so that the resulting light 440 can be a complex reflected and/or refracted light. It is to be further appreciated that although the light 440 is illustrated being directed at one side of the mask 430, that the light 440 may be directed at either and/or both sides of the mask 430. The scatterometry and/or reflectometry analysis can include comparing one or more scatterometry and/or reflectometry signatures associated with the reflected light 440 to one or more scatterometry and/or reflectometry signatures stored in a signature data store 470. Such signatures may be generated, for example, by combining phase, polarization and/or intensity information associated with the reflected light.

As fabrication progresses, light reflecting from the mask 420 may produce various signatures. The sequence in which such signatures are generated can be employed to determine the rate at which fabrication is progressing and also to predict times when fabrication may be substantially completed and/or times when an ex-situ quality control analysis may be appropriate. For example, at a first point in time T1, light reflected from the mask 420 may produce a signature S1 that indicates that openings (e.g., aperture 430) with a first width W1, depth D1 and slope angles SA1 have been produced and that a test grating should be probed at a second point in time T2 and a third point in time T3. Thus, at the second point in time T2, light reflected from the mask 420 may produce a signature S2 that indicates that openings with a second width W2, depth D2 and slope angles SA2 have been produced and at a third point in time T3, light reflected from the mask 420 may produce a signature S3 that indicates that lines with a third width W3, depth D3 and slope angles SA3 have been produced. Analyzing the sequence of signatures, and the time required to produce transitions between such signatures can facilitate determining whether fabrication is progressing at an acceptable rate, can facilitate predicting optimal times to pause a fabrication process to probe the fabrication process and can facilitate determining when fabrication should be terminated. Feedback information can be generated from such sequence analysis to maintain, increase and/or decrease the rate at which fabrication processes (e.g., etching) progresses. For example, one or more photoresist formulae and/or concentrations can be altered to affect the etching rate based on the signature sequence analysis.

The signature data can be stored in data structures including, but not limited to one or more lists, arrays, tables, databases, stacks, heaps, linked lists and data cubes. The signature data store 470 can reside on one physical device and/or may be distributed between two or more physical devices (e.g., disk drives, tape drives, memory units). Analyses associated with the reflected light and/or the signatures stored in the signature data store 470 can be employed to control one or more fabrication parameters (e.g., formula, concentration, time, angle) and in the present invention can be employed to terminate and/or pause fabrication, for example.

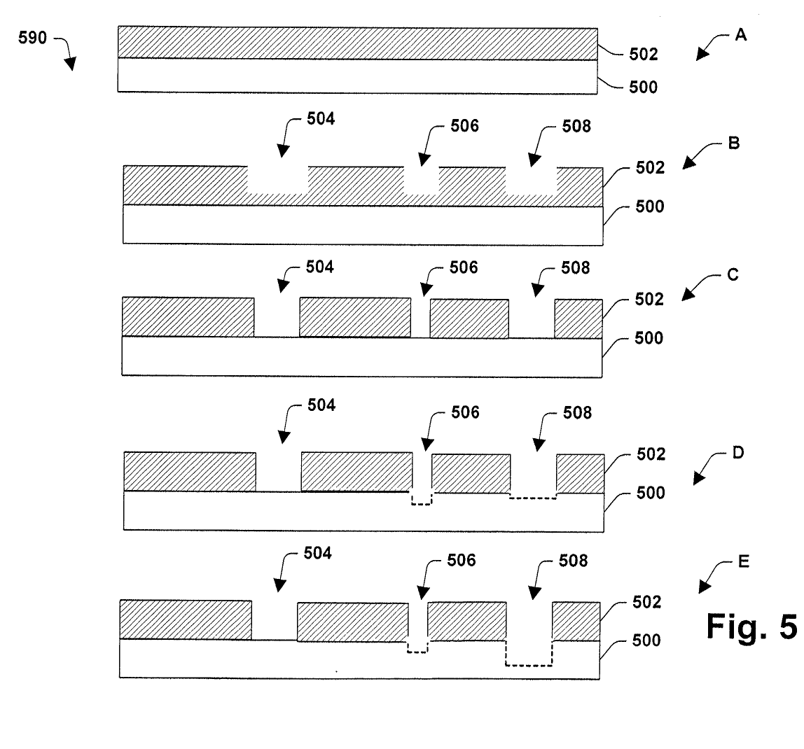

Turning now to FIG. 5, a phase shift mask 590 is illustrated at five different stages of an aperture fabrication process At stage A, a quartz layer 500 and a chrome layer 502 have been prepared for processing, but no apertures have been processed (e.g., etched) into either the quartz layer 500 or the chrome layer 502. At stage B, three apertures 504, 506 and 508 have been processed into the chrome layer 502. The present invention facilitates monitoring properties including, but not limited to, the depth, width and/or profile of the apertures 504, 506 and 508 via scatterometry. At stage B, a determination can be made concerning whether the depth, width and/or profile of one or more of the apertures 504, 506 and 508 indicates that further processing would be beneficial. Thus, at stage C, the mask 590 has been further processed to deepen the apertures 504, 506 and 508. At stage C, a determination can similarly be made that one or more of the apertures 504, 506 and 508 require further processing. Thus, at stage D, the mask 590 has been further processed to deepen the apertures 506 and 508, while the aperture 504 has not been further processed. At stage D, a determination can similarly be made that one or more of the apertures 504, 506 and 508 require further processing. Thus, at stage E, the mask 590 has been further processed to deepen the aperture 508, while the apertures 504 and 506 have not been further processed. The present invention thus enables fabricating apertures of differing depths, widths and/or profiles where the fabrication of the different depths are monitored and controlled. Enabling fabrication of apertures of varying widths, depths and/or profiles thus enables controlling diffraction and/or phase shifting of light waves that pass through the apertures, with a resulting increase in the fidelity of image transfer.

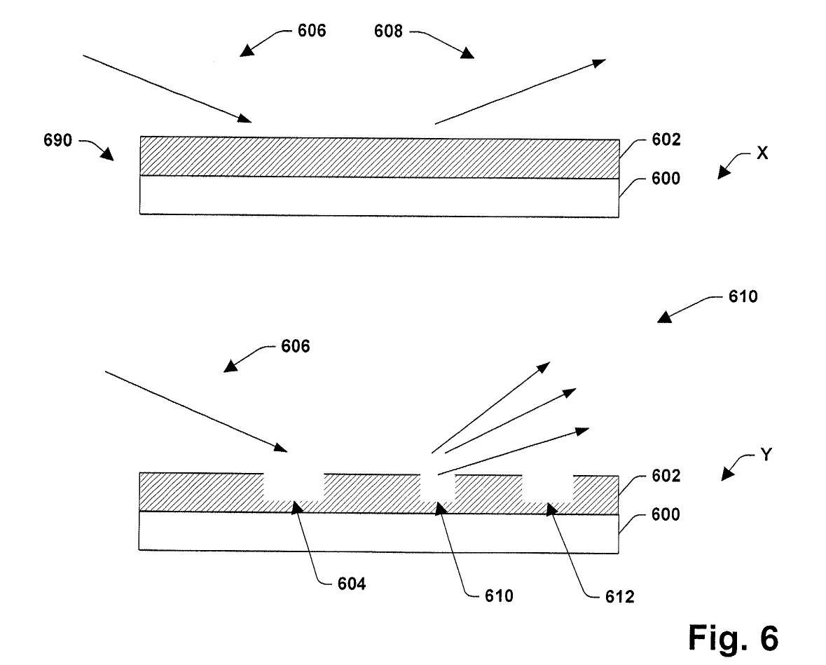

Turning now to FIG. 6, a phase shift mask 690 is illustrated with a light beam 606 directed onto the surface of the mask 690. At stage X of a mask fabrication process, the light beam 606 may reflect off the substantially planar surface of the mask 690, as illustrated by reflected light beam 608. But at stage Y of the fabrication process, the light beam 606 may reflect and/or diffract off the no longer substantially planar surface of the mask 690, as illustrated by the beams 610. It is to be appreciated that although one beam 606 is illustrated being directed at one side of the mask 690, that beams may be directed at either and/or both sides of the mask 690. The chrome layer 602, having been etched with the apertures 604, 610 and 612 will reflect the light beam 606 and may also diffract the light beam 606 into one or more resulting light beams 610. The light beams 610 will be reflected and/or diffracted into different patterns (signatures) that may be analyzed to determine properties including, but not limited to, the width, depth and/or profiles of the apertures 604, 610 and 612. Thus, the fabrication process may be controlled via feedback information generated from such analyses. In an alternative example of the present invention, the apertures, and/or one or more gratings fabricated on the mask are analyzed after the mask 690 is substantially complete. Thus, the analyses may be employed, for example, in quality control processes to facilitate selecting masks that have been fabricated within pre-determined tolerances.

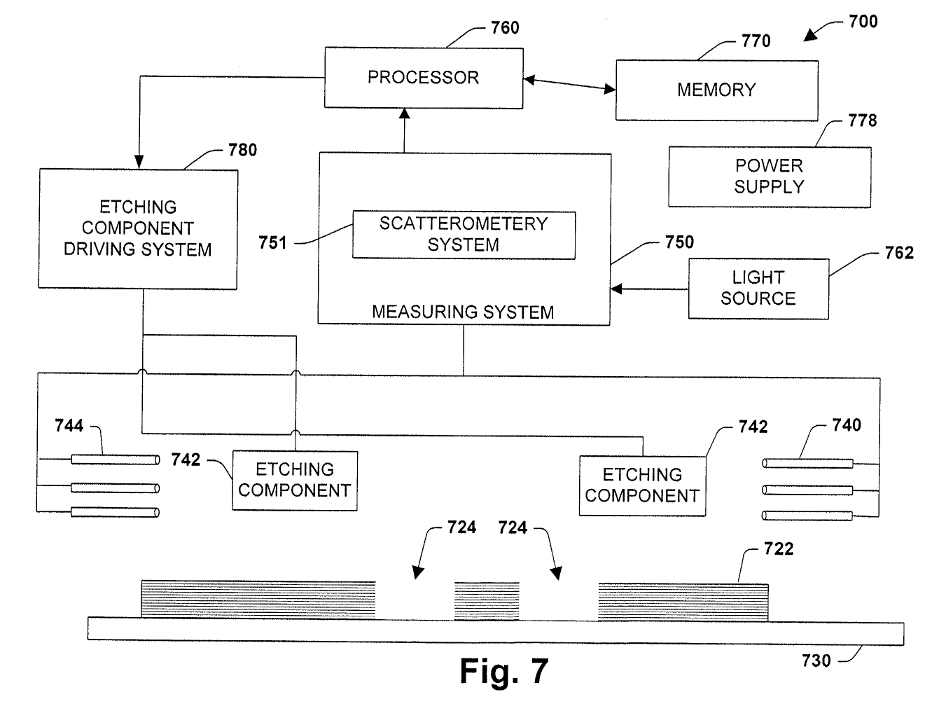

Turning now to FIG. 7, a system 700 for measuring, monitoring and/or in-situ controlling fabrication of apertures 724 in an alternating aperture phase shift mask 722 is further illustrated. In an alternative example of the present invention, the system 700 is employed in ex-situ quality control applications. One or more etching components 742 will etch the apertures 724 in the mask 722. One or more light sources 744 project light onto respective portions of the mask 722. A portion of the mask 722 may have one or more apertures 724 on that portion. Furthermore, in one example of the present invention, a portion may have one or more gratings fabricated thereon. Light reflected by the mask 722, gratings and/or apertures 724 is collected by one or more light detecting components 740, and processed by an opening parameter measuring system 750 to measure at least one parameter relating to the opening fabrication. The reflected light is processed with respect to the incident light in measuring the various parameters. The depth, width and/or profiles of the apertures 724 will cause the reflected light to be reflected in different, quantifiable manners. The reflected light may thus generate aperture signatures, which can be used to allow feedback control of the etching components via the etching component driving system 780.

The measuring system 750 includes a scatterometry system 751. It is to be appreciated that any suitable scatterometry system may be employed to carry out the present invention and that such systems are intended to fall within the scope of the claims appended hereto. A source of light 762 (e.g., a laser) provides light to the one or more light sources 744 via the measuring system 750. Preferably, the light source 762 is a frequency stabilized laser, however, it will be appreciated that any laser or other light source (e.g., laser diode or helium neon (HeNe) gas laser) suitable for carrying out the present invention may be employed. One or more light detecting components 740 (e.g., photo detector, photo diodes) collect light reflecting from the apertures 724 and/or gratings.

A processor 760 receives the measured data from the measuring system 750 and determines the depth, width and/or profiles of the apertures 724 and/or gratings. The processor 760 is operatively coupled to the measuring system 750 and is programmed to control and operate the various components within the system 700 in order to carry out the various functions described herein. The processor, or CPU 760, may be any of a plurality of processors, such as the AMD Athlon, K7 and/or other similar and compatible processors. The manner in which the processor 760 can be programmed to carry out the functions relating to the present invention will be readily apparent based on the description provided herein.

A memory 770, which is operatively coupled to the processor 760, is also included in the system 700 and serves to store program code executed by the processor 760 for carrying out operating functions of the system 700 as described herein. The memory 770 also serves as a storage medium for temporarily storing information such as aperture width, depth and/or profile requirements, aperture signature tables, aperture coordinate tables, aperture sizes, aperture shapes, scatterometry information, and other data that may be employed in carrying out the present invention.

A power supply 778 provides operating power to the system 700. Any suitable power supply (e.g., battery, line power) may be employed to carry out the present invention. The processor 760 is also coupled to an etching component driving system 780 that drives the etching components 742. The processor 760 controls the etching component driving system 780 to selectively control the etching components 742. The processor 760 monitors the apertures 724 via the signatures generated by reflected and/or diffracted light, and selectively regulates the etching of the apertures 724 via the corresponding etching components 742. Such regulation enables controlling the shape, depth and/or width of the apertures 724 and thus enables the phase shifting employed in phase shift masking, which in turn improves fidelity of image transfer in a lithographic process. Improved precision of image transfer enables smaller feature sizes and thus enables higher packing densities.

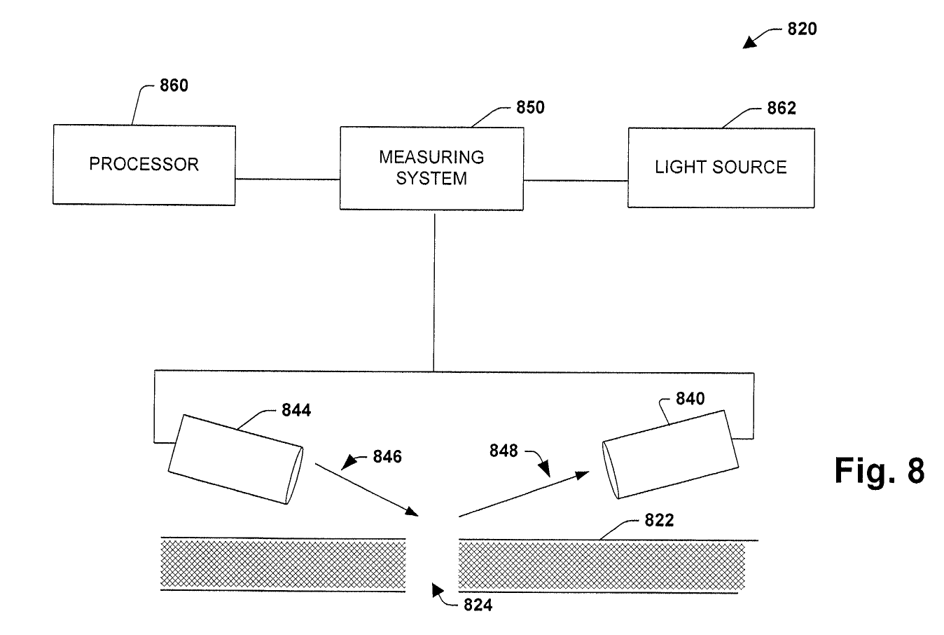

FIG. 8 illustrates a system 820 being employed to measure the width, depth and/or profile of an aperture 824 via light reflected from the aperture 824. The light source 844 directs a light 846 incident to the surface of the mask 822. The angle of a light 848 reflected and/or diffracted from the surface of the mask 822 will vary in accordance with the width, depth and/or profile of the aperture 824. The light detecting component 840 collects the reflected and/or diffracted light 848, pass the collected light, and/or data concerning the collected light to the measuring system 850. The measuring system 850 processes the reflected light 848 and/or data concerning the reflected light 848 in accordance with scatterometry techniques to provide the processor 860 with data corresponding to the depth, width and/or profile of the aperture 824 in the mask 822. The reflected light 848 may generate a signature that can be compared to one or more signatures to determine whether the etching process should continue. For example, the signature may indicate that the aperture 824 has not reached a desired depth and that further etching should occur.

In an alternative example of the present invention, the signature may be employed to determine whether a mask that is substantially complete should be scrapped. For example, the signature may indicate that the aperture 824 has not achieved desired critical dimensions (e.g., depth, width, profile).

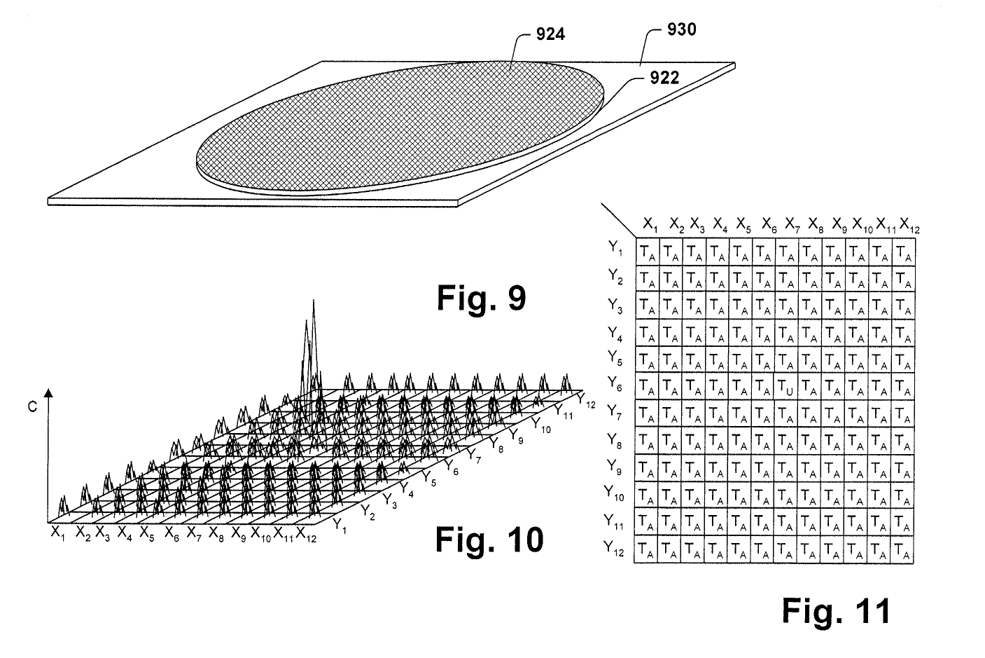

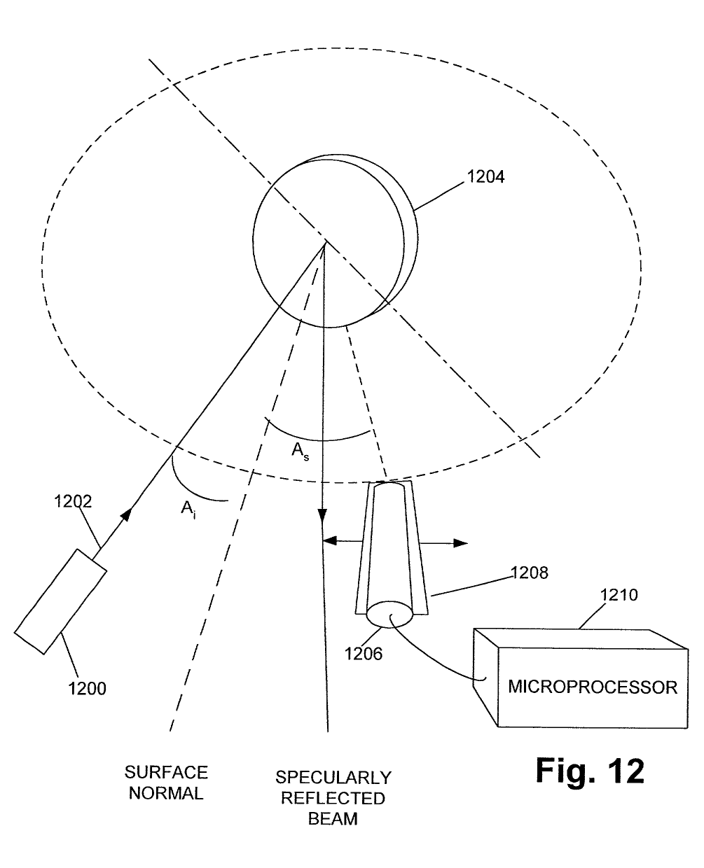

Turning now to FIGS. 9-11 a chuck 930 is shown in perspective supporting a mask 922 whereupon one or more apertures 924 and/or gratings may be located. The mask 922 may be divided into a grid pattern as shown in FIG. 10. Each grid block (XY) of the grid pattern corresponds to a particular portion of the mask 922, and each grid block may have one or more apertures 924 and/or gratings associated with that grid block. Portions can be individually monitored for properties including, but not limited to, aperture width, depth and profile, and each portion may be individually controlled for etching. It is to be appreciated that although one or more etching components can be associated with each grid block, that a greater or lesser number of etching components may be employed in the present invention. Furthermore, it is to be appreciated that the present invention can be employed without etching components in, for example, an ex-situ quality control application.

In FIG. 10, one or more apertures and/or gratings in respective portions of a mask (X₁Y₁ . . . X₁₂, Y₁₂) are being monitored for depth and/or width. The signatures for the apertures and/or gratings are shown. It is to be appreciated that although FIG. 10 illustrates the mask 922 being mapped (partitioned) into 144 grid block portions, the mask 922 may be mapped with any suitable number of portions and any suitable number of apertures 924 and/or gratings may be fabricated thereon. Given the set of signatures recorded in FIG. 10, it may be determined that an undesirable aperture fabrication condition exists for one or more apertures and/or gratings on the mask 922. Accordingly, a processor may drive one or more etching components to attempt to bring the aperture with the undesirable etching condition to a desired depth, width and/or profile, for example. It is to be appreciated that the etching components may be driven so as to increase or decrease the rate of etching and/or to change one or more etching parameters (e.g., direction), for example. When the processor determines than the etching process, as determined by analyzing the signatures, has reached a desired condition, the etching may be terminated. It is possible that a determination may be made that a desired width, depth and/or profile may not be achieved, at which point the mask may be marked for destruction, for example. While the discussion of FIG. 10 concerns primarily etching, it is to be appreciated that the present invention may be employed with other mask fabrication processes, and that etching is merely illustrative, and is not intended to be limiting.

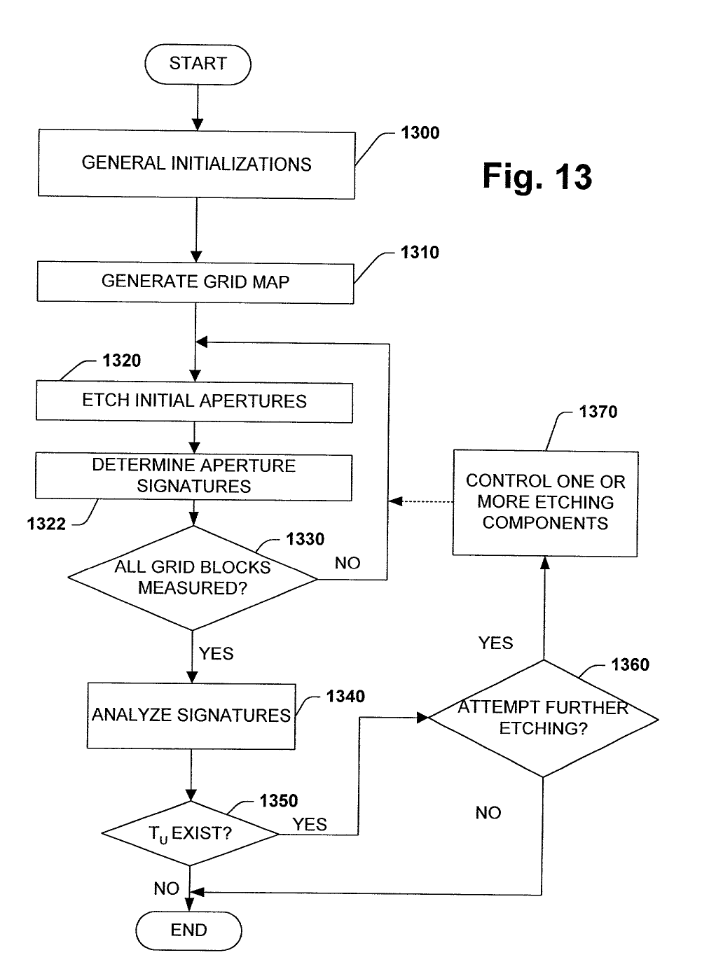

FIG. 11 illustrates a table of acceptable and unacceptable signatures. It can be seen that the signatures are acceptable except a signature for grid X₇Y₆. The set of signatures depicted in FIG. 11 can be analyzed collectively as a master signature, can be analyzed in subsets to evaluate, for example, intermediate etching progress, and/or can be analyzed individually to determine whether an acceptable etching condition exists. The analysis of the signatures can be employed in-situ to control the etching component driving system 780 (FIG. 7), so that finer depth, width and/or profile control may be achieved. In one example of the present invention, the analysis of the signatures can be employed ex-situ to determine whether a substantially completed mask has been fabricated within desired tolerances.

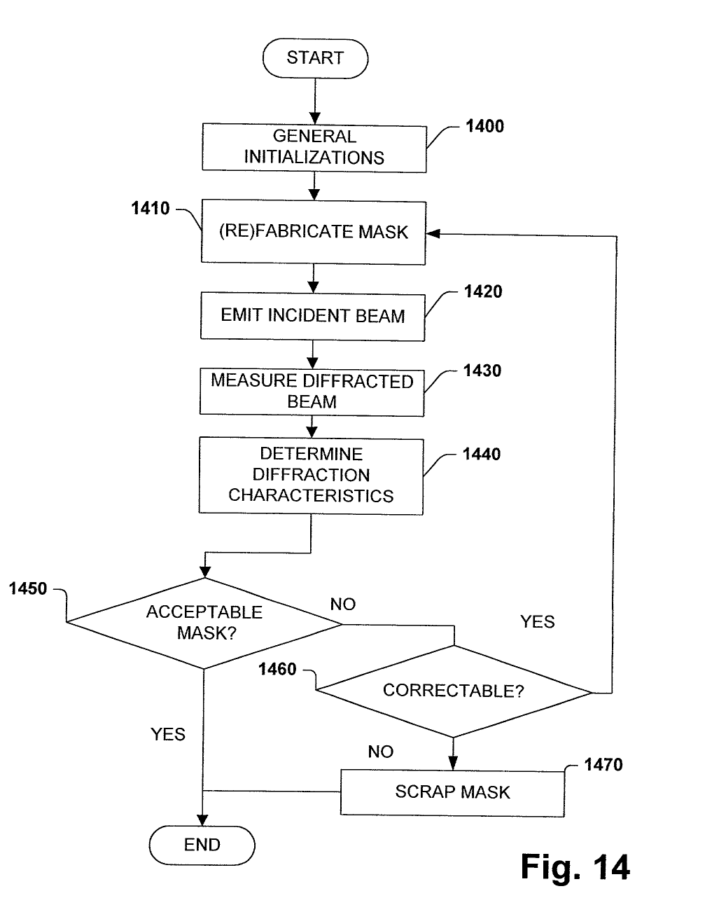

FIG. 12 illustrates an exemplary scatterometry system collecting reflected and/or diffracted light. Light from a laser 1200 is brought to focus in any suitable well-known manner to form a beam 1202. A sample, such as a mask 1204 is placed in the path of the beam 1202 and a photo detector or photo multiplier 1206 of any suitable well-known construction. Different detector methods may be employed to determine the scattered power. To obtain a grating pitch, the photo detector or photo multiplier 1206 may be mounted on a rotation stage 1208 of any suitable well-known design. A microprocessor 1210, of any suitable well-known design, may be used to process detector readouts, including, but not limited to, angular locations of different diffracted orders leading to diffraction grating pitches being calculated. Thus, light reflected and/or diffracted from the sample 1204 may be accurately measured.

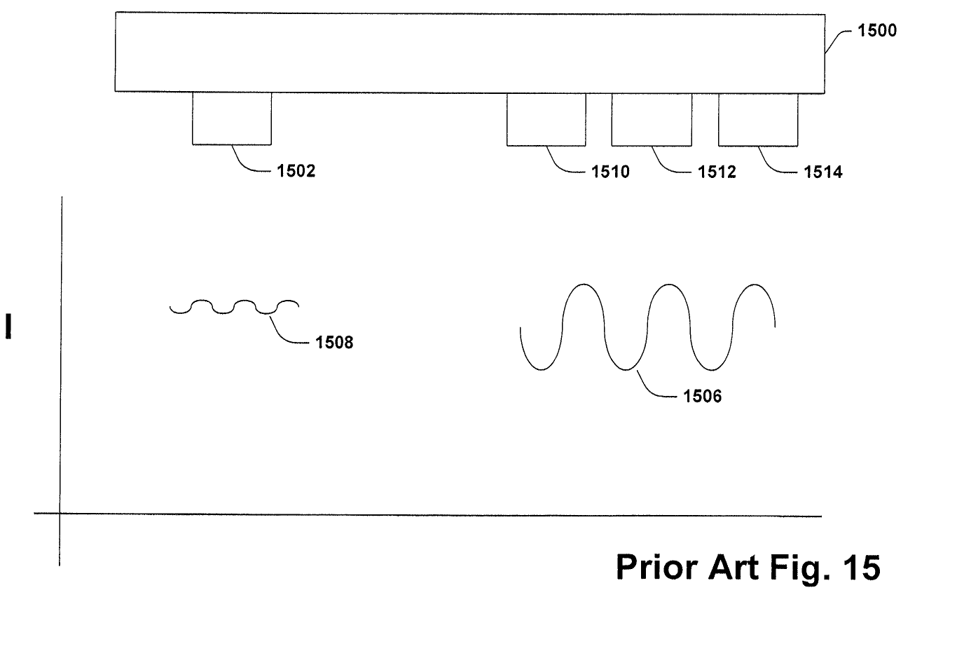

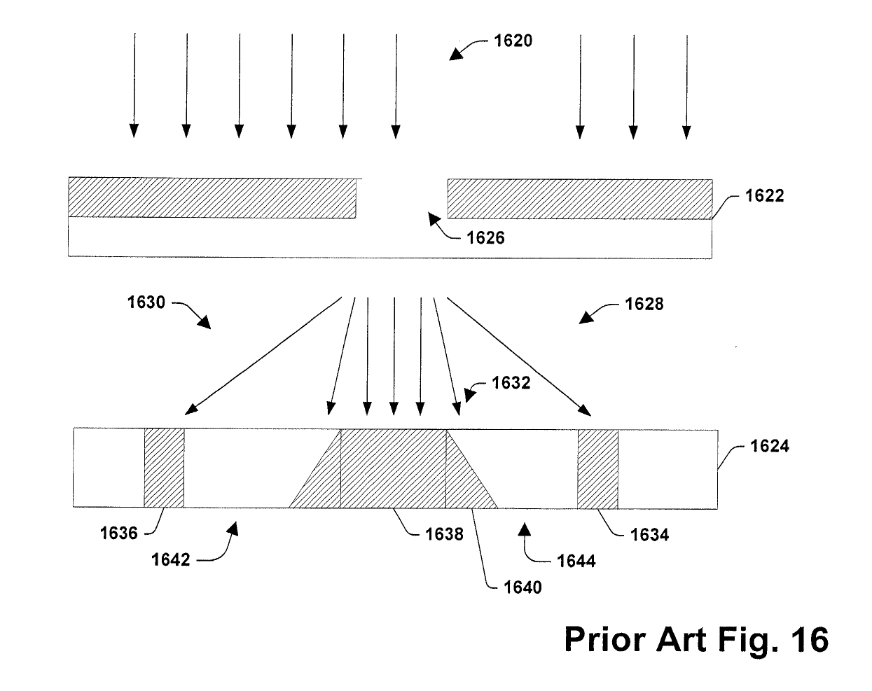

In view of the exemplary systems shown and described above, methodologies that may be implemented in accordance with the present invention, will be better appreciated with reference to the flow diagrams of FIG. 13 and 14. While, for purposes of simplicity of explanation, the methodologies of FIG. 13 and FIG. 14 are shown and described as a series of blocks, it is to be understood and appreciated that the present invention is not limited by the order of the blocks, as some blocks may, in accordance with the present invention, occur in different orders and/or concurrently with other blocks from that shown and described herein. Moreover, not all illustrated blocks may be required to implement a methodology in accordance with the present invention.

FIG. 13 is a flow diagram illustrating one particular methodology for carrying out the present invention. At 1300, a processor performs general initializations to an etching system. The initializations may include, but are not limited to, establishing desired aperture depths, widths and/or profiles, establishing data communications, fetching desired aperture signatures and positioning fabrication means and products. At 1310, the processor maps at least a portion of a mask into a plurality of grid blocks “XY”. At 1320, one or more apertures and/or gratings are initially etched in a layer of the mask (e g., substrate, opaque material). At 1322, aperture signature determinations are made with respect to the various wafer portions mapped by the respective grid blocks XY. At 1330, the processor determines if all grid block signatures have been taken. If the determination at 1330 is NO, then the processor returns to 1320. If the determination at 1330 is YES, then at step 1340, the processor analyzes the signature or signatures against a table of acceptable signatures. At 1350, the processor determines if the signatures are acceptable. If the signatures are acceptable, the processor ends the iteration of the etching process. If at 1350 an unacceptable signature is found, the process advances to 1360 where a determination is made concerning whether further etching attempts will be made. If no further attempts are to be made, then the mask can be marked for further processing and/or destruction and alarms may be sent to subsequent methods and/or apparatus concerning the unacceptably etched portion of the mask, after which the etching process concludes. In one example of the present invention, at 1350, rather than the determination concerning whether a single unacceptable signature has been found, the determination may concern whether an unacceptable number of signatures, and/or whether a cumulative error indicated by the collection of signatures has been received.

If the determination at 1360 is YES, then at 1362 the processor controls relevant etching components to further etch the apertures and to attempt to achieve a more precise depth and/or width of the apertures. The present iteration is then ended and the process returns to 1320 to perform another iteration.

It is to be appreciated that while the blocks in FIG. 13 are shown in a linear order, that emitting the incident beam, measuring the diffracted beam and determining whether the fabrication process has produced apertures of a desired width, depth and/or profile may occur simultaneously to facilitate providing in situ feedback and control.

FIG. 14 is a flow diagram illustrating another particular methodology for carrying out an aspect of the present invention. At 1400 general initializations and/or configurations are performed. At 1410, the fabrication (e.g., etching) of the apertures begins. At 1420, an incident beam is emitted onto one or more apertures and/or gratings and at 1430 the beam diffracted from the one or more apertures and/or gratings is measured. At 1440, the signatures from the apertures and/or gratings upon which the incident beam of 1420 was directed and which produced the diffracted beam of 1430 are analyzed. At 1450 a determination is made concerning whether an acceptable mask has been produced. It is to be appreciated that while the method illustrated in FIG. 13 may be practiced in-situ to control fabrication, the method illustrated in FIG. 14 may be employed ex-situ in, for example, quality control applications. If the determination at 1450 is YES, then an acceptable mask has been produced and the mask may be forwarded for further processing and/or use. If the determination at 1450 is NO, then processing proceeds to 1460, where a determination is made concerning whether the fabricated mask is correctable. If the determination at 1460 is NO, then at 1470 the mask may be marked for discard and processing will conclude. But if the determination at 1460 is YES, then processing can return to 1410 where refabrication of the mask may occur.

Scatterometry is a technique for extracting information about a surface upon which an incident light has been directed. Information concerning properties including, but not limited to, dishing, erosion, profile, thickness of thin films and critical dimensions of features present on and/or in the surface can be extracted. The information can be extracted by comparing the phase and/or intensity of the light directed onto the surface with phase and/or intensity signals of a complex reflected and/or diffracted light resulting from the incident light reflecting from and/or diffracting through the surface upon which the incident light was directed. The intensity and/or the phase of the reflected and/or diffracted light will change based on properties of the surface upon which the light is directed. Such properties include, but are not limited to, the chemical properties of the surface, the planarity of the surface, features on the surface, voids in the surface, and the number and/or type of layers beneath the surface.

Different combinations of the above-mentioned properties will have different effects on the phase and/or intensity of the incident light resulting in substantially unique intensity/phase signatures in the complex reflected and/or diffracted light. Thus, by examining a signal (signature) library of intensity/phase signatures, a determination can be made concerning the properties of the surface. Such substantially unique phase/intensity signatures are produced by light reflected from and/or refracted by different surfaces due, at least in part, to the complex index of refraction of the surface onto which the light is directed. The complex index of refraction (N) can be computed by examining the index of refraction (n) of the surface and an extinction coefficient (k). One such computation of the complex index of refraction can be described by the equation:

N=n−jk

where j is an imaginary number.

The signal (signature) library can be constructed from observed intensity/phase signatures and/or signatures generated by modeling and simulation. By way of illustration, when exposed to a first incident light of known intensity, wavelength and phase, a first feature on a wafer can generate a first phase/intensity signature. Similarly, when exposed to the first incident light of known intensity, wavelength and phase, a second feature on a wafer can generate a second phase/intensity signature. For example, a line of a first width may generate a first signature while a line of a second width may generate a second signature. Observed signatures can be combined with simulated and modeled signatures to form the signal (signature) library. Simulation and modeling can be employed to produce signatures against which measured phase/intensity signatures can be matched. In one exemplary aspect of the present invention, simulation, modeling and observed signatures are stored in a signal (signature) library containing over three hundred thousand phase/intensity signatures. Thus, when the phase/intensity signals are received from scatterometry detecting components, the phase/intensity signals can be pattern matched, for example, to the library of signals to determine whether the signals correspond to a stored signature.

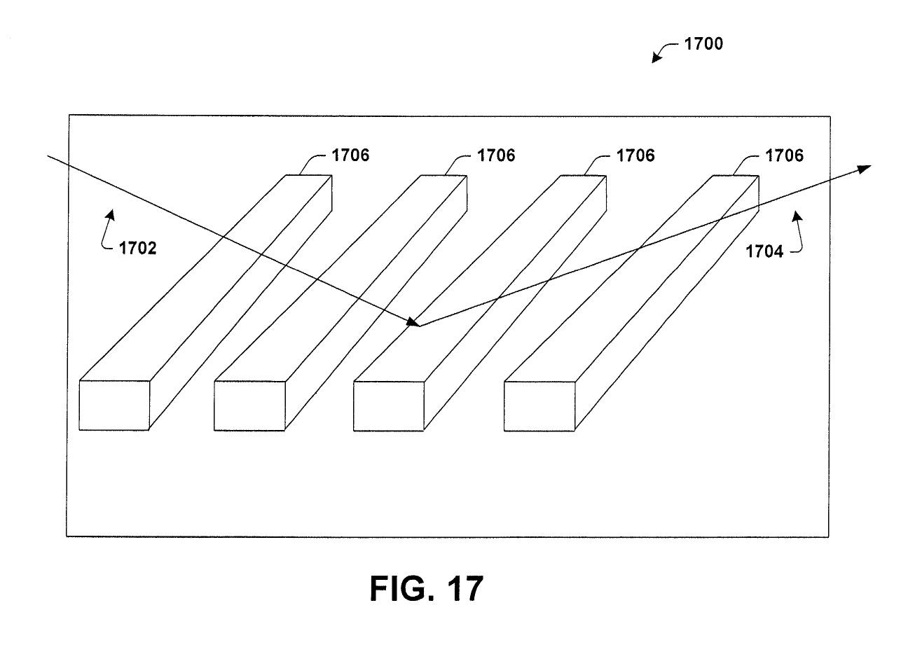

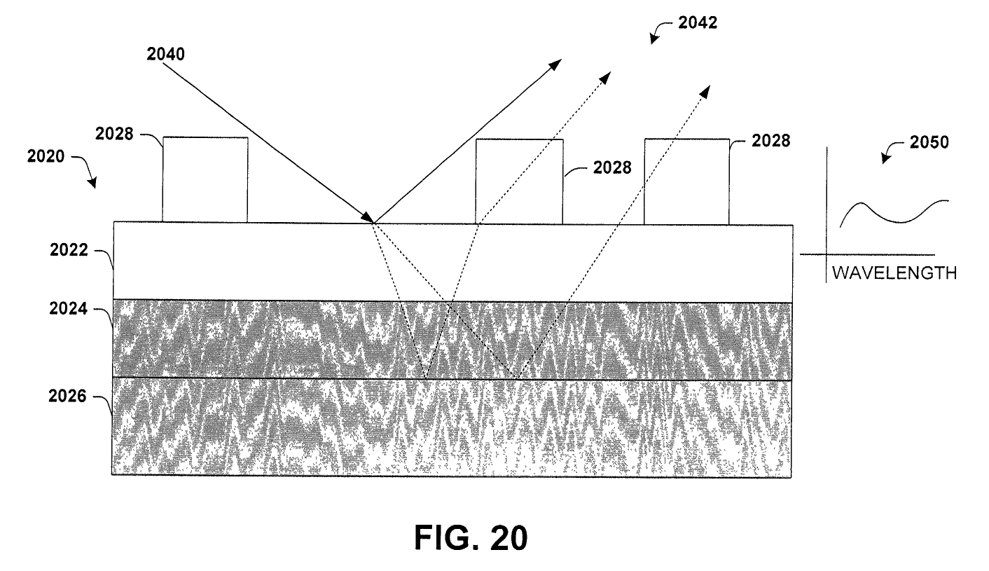

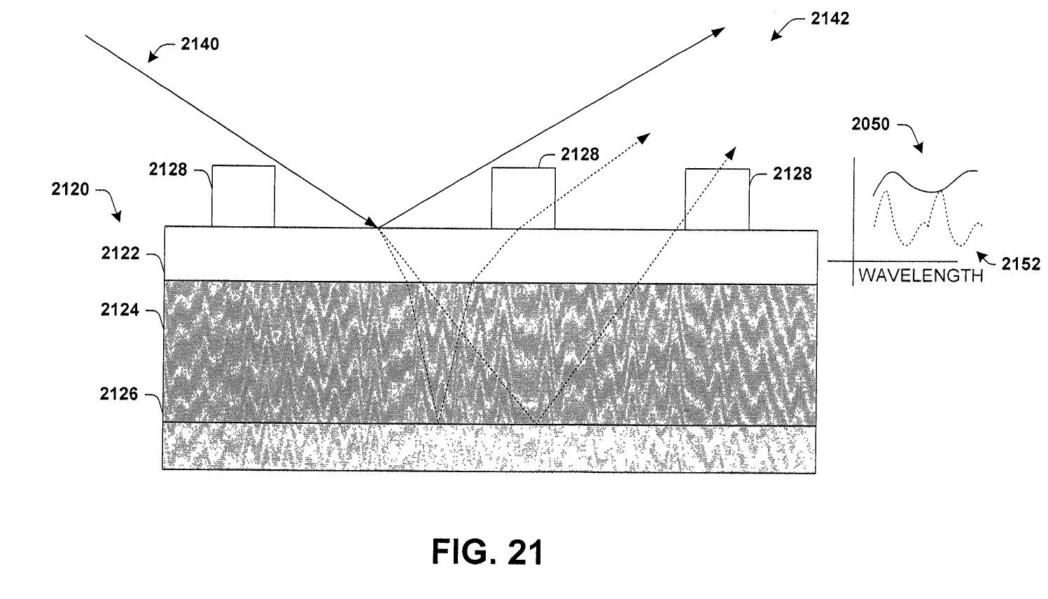

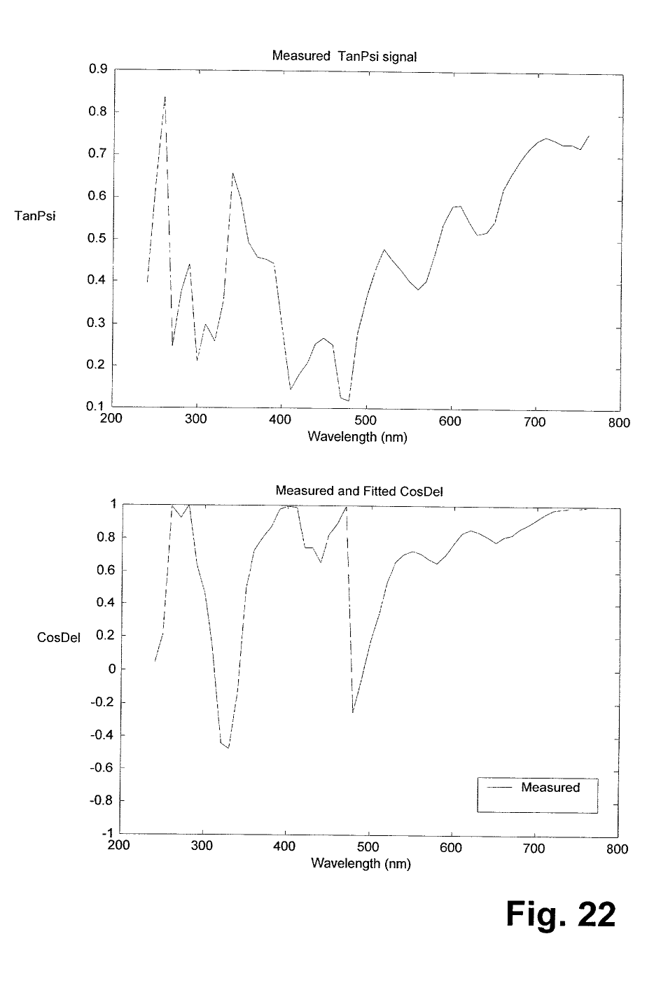

To illustrate the principles described above, reference is now made to FIGS. 17 through 22. Referring initially to FIG. 17, an incident light 1702 is directed at a surface 1700, upon which one or more features 1706 may exist. In FIG. 17 the incident light 1702 is reflected as reflected light 1704. The properties of the surface 1700, including but not limited to, thickness, uniformity, planarity, chemical composition and the presence, critical dimensions (CDs), profiles of such features, can affect the reflected light 1704. In FIG. 17, the features 1706 are raised upon the surface 1700. The phase and intensity of the reflected light 1704 can be measured and plotted, as shown, for example, in FIG. 22. The phase 2050 (FIG. 20) of the reflected light 1704 can be plotted, as can the intensity 2152 (FIG. 21) of the reflected light 1704. Such plots can be employed to compare measured signals with signatures stored in a signature library using techniques like pattern matching, for example.

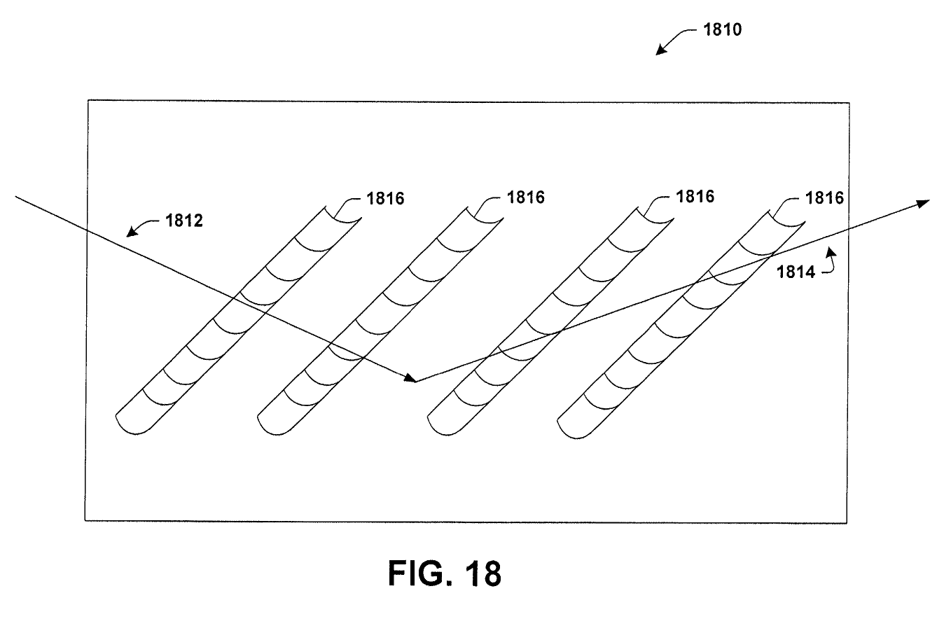

Referring now to FIG. 18, an incident light 1812 is directed onto a surface 1810 upon which one or more depressions 1816 appear. The incident light 1812 is reflected as reflected light 1814. Like the one or more features 1706 (FIG. 17) may affect an incident beam, so too may the one or more depressions 1816 and/or the CDs and profile of the depressions 1816 affect an incident beam. Thus, it is to be appreciated that scatterometry can be employed to measure features appearing on a surface, features appearing in a surface, and properties of a surface itself, regardless of features.

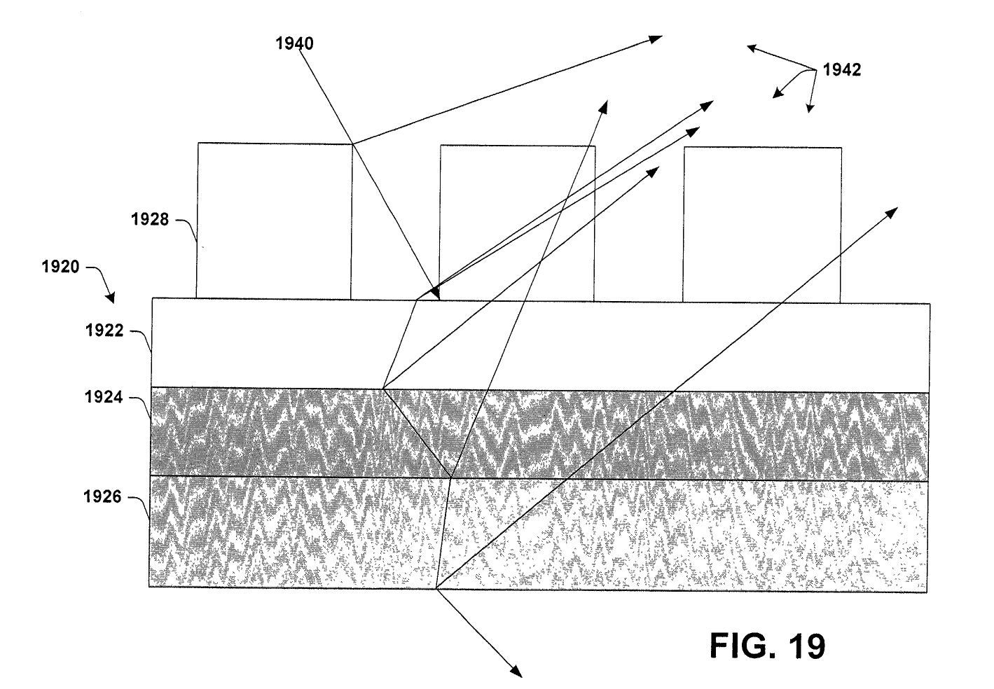

Turning now to FIG. 19, complex reflections and refractions of an incident light 1940 are illustrated. The reflection and refraction of the incident light 1940 can be affected by factors including, but not limited to, the presence of one or more features 1928, and the composition of the substrate 1920 upon which the features 1928 reside. For example, properties of the substrate 1920 including, but not limited to the thickness of a layer 1922, the chemical properties of the layer 1922, the opacity and/or reflectivity of the layer 1922, the thickness of a layer 1924, the chemical properties of the layer 1924, the opacity and/or reflectivity of the layer 1924, the thickness of a layer 1926, the chemical properties of the layer 1926, and the opacity and/or reflectivity of the layer 1926 can affect the reflection and/or refraction of the incident light 1940. Thus, a complex reflected and/or refracted light 1942 may result from the incident light 1940 interacting with the features 1928, and/or the layers 1922, 1924 and 1926. Although three layers 1922, 1924 and 1926 are illustrated in FIG. 19, it is to be appreciated that a substrate can be formed of a greater or lesser number of such layers.

Turning now to FIG. 20, one of the properties from FIG. 19 is illustrated in greater detail. The substrate 2020 can be formed of one or more layers 2022, 2024 and 2026. The phase 2050 of the reflected and/or refracted light 2042 can depend, at least in part, on the thickness of a layer, for example, the layer 2024. Thus, in FIG. 21, the phase 2152 of the reflected light 2142 differs from the phase 2050 due, at least in part, to the different thickness of the layer 2124 in FIG. 21

Thus, scatterometry is a technique that can be employed to extract information about a surface and/or features upon which an incident light has been directed. The information can be extracted by analyzing phase and/or intensity signals of a complex reflected and/or diffracted light. The intensity and/or the phase of the reflected and/or diffracted light will change based on properties of the surface and/or features upon which the light is directed, resulting in substantially unique signatures that can be analyzed to determine one or more properties of the surface and/or features upon which the incident light was directed.

Described above are preferred embodiments of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claim.

What is claimed is:

1. A system for monitoring the etching of apertures in an alternating aperture phase shift mask, comprising:
one or more fabricating components operative to fabricate one or more mask features;
a fabricating component driving system operably connected to the one or more fabricating components, the fabricating component driving system operable to drive the one or more fabricating components;
a system for directing light on to at least one of the one or more features; and
a measuring system for measuring feature parameters based on a light reflected and/or refracted from the one or more features.

2. The system of claim 1, comprising a processor operatively coupled to the measuring system and the fabricating component driving system.

3. The system of claim 2 where the processor is adapted to receive feature data from the measuring system and to at least partially control the one or more fabricating components to regulate fabricating the one or more features.

4. The system of claim 3 where the fabricating components are etching components.

5. The system of claim 4 where the features comprise at least one of an aperture and a grating.

6. The system of claim 3 where the measuring system comprises a scatterometry system for processing the light reflected from the one or more features.

7. The system of claim 6 where the fabricating components are etching components.

8. The system of claim 7 where the features comprise at least one of an aperture and a grating.

9. The system of claim 6 where the processor maps the mask into a plurality of grid blocks and makes a determination of fabrication conditions at the one or more grid blocks.

10. The system of claim 9, where the fabrication conditions comprise at least one of the depth, width and profile of the features.

11. The system of claim 10 where the processor determines the existence of an unacceptable fabrication condition for the one or more features based upon a determined feature signature differing from an acceptable feature signature.

12. The system of claim 10 where the processor controls the one or more fabricating components to regulate fabricating the one or more features on the mask.

13. The system of claim 12 where the features comprise at least one of an aperture and a grating.

14. The system of claim 13 where the fabricating components are etching components.

15. A system for monitoring the profile of an aperture on an alternating aperture phase shift mask, the system comprising:
a system for directing light onto an alternating aperture phase shift mask; and
a measuring system for measuring one or more aperture parameters based on a light reflected from the aperture.

16. The system of claim 15 where the aperture parameters comprise at least one of aperture depth, aperture width and aperture wall slope.

17. The system of claim 16 comprising a processor adapted to receive aperture data from the measuring system and to facilitate determining whether the alternating aperture phase shift mask has been fabricated within one or more pre-determined tolerances.

18. The system of claim 17 where the pre-determined tolerances comprise at least one of aperture depth, aperture width and aperture wall slope.

19. The system of claim 18 where the measuring system comprises a scatterometry system for processing the light reflected from an aperture to determine an aperture signature.

20. The system of claim 19 where the processor determines whether the mask has been fabricated within one or more pre-determined tolerances based upon a determined aperture signature differing from an acceptable aperture signature.

21. A method for monitoring and controlling aperture etching in an alternating aperture phase shift mask, comprising:
etching one or more apertures on the alternating aperture phase shift mask;
directing light onto at least one of the one or more apertures;
collecting light reflected from the at least one aperture;
employing scatterometry to analyze the reflected light to determine at least one of the depth, shape, location, profile and width of the at least one aperture; and
selectively controlling the etching of the one or more apertures in the mask.

22. The method of claim 21 comprising:
etching one or more gratings on the alternating aperture phase shift mask;
directing light onto at least one of the one or more gratings;
collecting light reflected from the at least one grating; and
employing scatterometry to analyze the reflected light to determine at least one of the depth, shape, location, profile and width of the at least one grating.

23. A method for determining whether an alternating aperture phase shift mask has been fabricated with desired aperture etching parameters, comprising:
etching one or more apertures on the alternating aperture phase shift mask;
directing light onto at least one of the one or more apertures;
collecting light reflected from the at least one aperture;
employing scatterometry to analyze the reflected light to determine at least one of the depth, shape, location, profile and width of the at least one aperture; and
determining the acceptability of the alternating aperture phase shift mask based on at least one of the depth, shape, location, profile and width of the at least one aperture.

24. The method of claim 23 comprising:
etching one or more gratings on the alternating aperture phase shift mask;
directing light onto at least one of the one or more gratings;
collecting light reflected from the at least one grating; and
employing scatterometry to analyze the reflected light to determine at least one of the depth, shape, location, profile and width of the at least one grating.

25. A system for controlling a process for etching openings in an alternating aperture phase shift mask, comprising:
means for sensing at least one of the shape, location, depth, width and opening wall slopes of one or more apertures on the mask;
means for etching one or more apertures on the mask; and
means for selectively controlling the etching of the one or more apertures based on analysis of data collected by the means for sensing the shape, location, depth, width and opening wall slopes of the one or more apertures.
